(19) United States
(12) Patent Application Publication
(10) Pub. No.: US 2026/0221988 A1
(43) Pub. Date: Jul. 30, 2026

(54) Data Encoding Method and Related Apparatus

(71) Applicant: HUAWEI TECHNOLOGIES CO., LTD., Shenzhen (CN)

(72) Inventors: Qinhui Huang, Shenzhen (CN); Jinsheng Li, Shenzhen (CN); Xiaoling Yang, Shenzhen (CN); Huixiao Ma, Shenzhen (CN)

(73) Assignee: HUAWEI TECHNOLOGIES CO., LTD., Shenzhen (CN)

(21) Appl. No.: 19/631,344

(22) Filed: Mar. 27, 2026

Related U.S. Application Data
(63) Continuation of application No. PCT/CN2024/114145, filed on Aug. 23, 2024.

(30) Foreign Application Priority Data
Sep. 28, 2023 (CN) 202311295101.1

(51) Int. Cl. H03M 13/11; H03M 13/00; H03M 13/09

(52) U.S. Cl. CPC H03M 13/11; H03M 13/09; H03M 13/6575

(57) ABSTRACT

In a data encoding method, for a first data stream obtained through outer encoding, inner encoding is performed on every consecutive k bits in the first data stream, where k is an odd number greater than 1. A total of (k−1)/2 bits may be obtained by performing an exclusive OR operation on every two of remaining bits other than one target bit in the k bits. Further, second FEC encoding is performed on a bit sequence that includes the (k−1)/2 bits and the target bit, to obtain p parity bits. n bits in an inner codeword obtained through inner encoding include the consecutive k bits and the p parity bits. In the data encoding method, an exclusive OR operation first and then encoding manner is used.

### CROSS-REFERENCE TO RELATED APPLICATIONS

This is a continuation of International Patent Application No. PCT/CN2024/114145 filed on Aug. 23, 2024, which claims priority to Chinese Patent Application No. 202311295101.1 filed on Sep. 28, 2023, which are hereby incorporated by reference in their entireties.

### TECHNICAL FIELD

Embodiments of this disclosure relate to the field of optical communication, and in particular, to a data encoding method and a related apparatus.

### BACKGROUND

Driven by continuous advancement of fifth generation (5G), cloud computing, big data, artificial intelligence, and the like, optical communication systems and optical transport networks (OTNs) are evolving toward large capacity and ultra-high speeds. Forward error correction (FEC) encoding is used to correct transmission bit errors, so that original data sent from a transmitter can be recovered from received data.

In a 400G ZR scenario, an optical module uses concatenated FEC (CFEC) as an error correction encoding scheme, which includes a staircase code as an outer code, and a double-bit extended Hamming code as an inner code. In a future 1.6 T ZR scenario, due to a significant increase in transmission rates, power consumption issues faced by existing CFEC schemes become more severe, and an encoding and decoding scheme with lower power consumption is urgently needed.

### SUMMARY

Embodiments of this disclosure provide a data encoding method and a related apparatus, to reduce encoding complexity without changing a length of an inner codeword and redundancy costs.

According to a first aspect, an embodiment of this disclosure provides a data encoding method. Consecutive k bits in a first data stream obtained through first FEC encoding are first obtained, and the first FEC encoding may be considered as outer encoding. k is an odd number greater than 1, the consecutive k bits include a bit set and a target bit, the bit set includes (k−1)/2 bit subsets, and each bit subset includes two bits. Then, inner encoding is performed on the consecutive k bits to obtain a codeword. A specific operation of the inner encoding is as follows: first, performing an exclusive OR operation on the two bits in each bit subset to obtain one bit, to obtain a total of (k−1)/2 bits; and then, performing second FEC encoding on a bit sequence that includes the (k−1)/2 bits and the target bit, to obtain p parity bits. The codeword obtained through inner encoding includes the consecutive k bits and the p parity bits, where p is an integer greater than or equal to 1.

In this implementation, for a first data stream obtained through outer encoding, inner encoding needs to be performed on every consecutive k bits in the first data stream, where k is an odd number greater than 1. A total of (k−1)/2 bits may be obtained by performing an exclusive OR operation on every two of remaining bits other than one target bit in the k bits. Further, second FEC encoding is performed on the bit sequence that includes the (k−1)/2 bits and the target bit, to obtain the p parity bits. n bits in an inner codeword obtained through inner encoding include the consecutive k bits and the p parity bits. It can be learned that, in embodiments of this disclosure, an exclusive OR operation first and then encoding manner is used. For example, (128, 119) codeword processing may be implemented via a (69, 60) encoder, so that encoding complexity is reduced without changing a length of the inner codeword and redundancy costs.

In some possible implementations, the two bits in each bit subset are two adjacent bits in the consecutive k bits, and selecting the two adjacent bits to perform an exclusive OR operation is easier to implement, thereby facilitating standardization.

In some possible implementations, the p parity bits are located after the consecutive k bits in the codeword, and the target bit is a last bit in the consecutive k bits; or the p parity bits are located before the consecutive k bits in the codeword, and the target bit is a 1^{st} bit in the consecutive k bits. In other words, the i bit or the last bit in an information sequence of the k bits is selected as the target bit, and a parity sequence of the p parity bits is arranged close to the target bit. This is more conducive to distribution of the information sequence and the parity sequence in the inner codeword.

In some possible implementations, after performing inner encoding on the consecutive k bits to obtain the codeword, the method further includes: performing symbol mapping and polarization distribution on eight bits from four bit subsets in a second data stream that includes at least one codeword to obtain one dual-polarization (DP)-16 quadrature amplitude modulation (QAM) symbol, where the four bit subsets are respectively mapped, through Gray mapping, to an I component in an X polarization direction, a Q component in the X polarization direction, an I component in a Y polarization direction, and a Q component in the Y polarization direction that are of the DP-16QAM symbol. In other words, any component of the DP-16QAM symbol is obtained by performing Gray mapping on two bits of one bit subset participating in the exclusive OR operation. Therefore, generally, at most one error bit occurs in two bits mapped to a same pulse amplitude modulation (PAM) 4 symbol, thereby reducing a likelihood of an error bit.

In some possible implementations, the second FEC encoding is Bose-Chaudhuri-Hocquenghem (BCH) encoding or extended BCH encoding over a finite field GF(2^{m}) with t-bit error correction, to enrich encoding modes that may be used for the inner encoding. GF refers to a finite field, or may be referred to as a Galois field, and 2^{m} represents an order of the finite field. Mt≤p, and

$$\frac{k + 1}{2} + p \leq {2}^{m} - 1 ,$$

that is, a value of m in GF(2^{m}) is not unique. For example, if the value of m is subtracted by 1 based on an original value, a quantity of parity bits may be reduced by t when encoding is performed in this manner, so that a bit rate of the codeword is increased and overheads of the codeword are reduced when a length of information bits is unchanged.

In some possible implementations, k=119, and GF(2^{m}) used in the second FEC encoding is GF(2⁸) or GF(2⁷). In a scenario in which k=119, implementability of the inner encoding is improved.

In some possible implementations, a length of the codeword is n, the second FEC encoding is the BCH encoding over GF(2^{m}) with t-bit error correction, and a correspondence among n, k, GF(2^{m}), t, and p is one of the following:

$$n = 133 , k = 119 , G F ( {2}^{m} ) = G F ( {2}^{7} ) , t = 2 , and p = 14 ; and$$

$$n = 13 \; 5 , k = 119 , G F ( {2}^{m} ) = G F ( {2}^{8} ) , t = 2 , and p = 16 .$$

In some possible implementations, a length of the codeword is n, the second FEC encoding is the extended BCH encoding over the finite field GF(2^{m}) with t-bit error correction, the p parity bits include a cyclic redundancy check (CRC) extended check field of q bits, and a correspondence among n, k, GF(2^{m}), t, p, and q is one of the following:

$$n = 128 , k = 119 , G F ( {2}^{m} ) = G F ( {2}^{7} ) , t = 1 , p = 9 , and q = 2 ;$$

$$n = 13 \; 4 , k = 119 , G F ( {2}^{m} ) = G F ( {2}^{7} ) , t = 2 , p = 15 , and q = 1 ;$$

$$n = 13 \; 5 , k = 119 , G F ( {2}^{m} ) = G F ( {2}^{7} ) , t = 2 , p = 16 , and q = 2 ;$$

$$n = 13 \; 6 , k = 119 , G F ( {2}^{m} ) = G F ( {2}^{8} ) , t = 2 , p = 17 , and q = 1 ; and$$

$$n = 13 \; 7 , k = 119 , G F ( {2}^{m} ) = G F ( {2}^{8} ) , t = 2 , p = 18 , and q = 2 .$$

According to a second aspect, an embodiment of this disclosure provides a data encoding method. Consecutive k bits in a first data stream obtained through first FEC encoding are first obtained, and the first FEC encoding may be considered as outer encoding. k is an integer greater than or equal to 3, the consecutive k bits include v bit subsets, each bit subset includes three bits, and v is an integer greater than or equal to 1. Then, inner encoding is performed on the consecutive k bits to obtain a codeword. A specific operation of the inner encoding is as follows: first, performing an exclusive OR operation on the three bits in each bit subset to obtain one bit, to obtain a total of v bits; and then, performing second FEC encoding on a bit sequence that includes the v bits, to obtain p parity bits. The codeword obtained through inner encoding includes the consecutive k bits and the p parity bits, where p is an integer greater than or equal to 1.

In this implementation, for a first data stream obtained through outer encoding, inner encoding needs to be performed on every consecutive k bits in the first data stream, where k is an odd number greater than 1. An exclusive OR operation is performed on every three bits in the k bits to obtain a total of v bits. Further, second FEC encoding is performed on the v bits, to obtain the p parity bits. n bits in an inner codeword obtained through inner encoding include the consecutive k bits and the p parity bits. It can be learned that, in embodiments of this disclosure, an exclusive OR operation first and then encoding manner is used. For example, (128, 119) codeword processing may be implemented via a (50, 41) encoder, so that encoding complexity is reduced without changing a length of the inner codeword and redundancy costs.

In some possible implementations, the three bits in each bit subset are consecutive three bits in the consecutive k bits, and selecting every consecutive three bits to perform an exclusive OR operation is easier to implement, thereby facilitating standardization.

In some possible implementations, k=v×3, that is, an exclusive OR operation may be performed on exactly every three bits in the k bits, and this has good practicability.

In some possible implementations, the consecutive k bits further include r target bits, where k=v×3+r, and r=1 or 2. Performing second FEC encoding on the bit sequence that includes the v bits to obtain the p parity bits includes: performing second FEC encoding on the bit sequence that includes the v bits and the r target bits, to obtain the p parity bits. In other words, this scheme may also be applied to a scenario in which k is not divisible by 3, thereby expanding scope of application scenarios of this scheme.

In some possible implementations, the p parity bits are located after the consecutive k bits in the codeword, and the target bits are last r bits in the consecutive k bits; or the p parity bits are located before the consecutive k bits in the codeword, and the target bits are first r bits in the consecutive k bits. In other words, the first r bits or the last r bits in an information sequence of the k bits are selected as the target bits, and a parity sequence of the p parity bits is arranged close to the target bit. This is more conducive to distribution of the information sequence and the parity sequence in the inner codeword.

In some possible implementations, after performing inner encoding on the consecutive k bits to obtain the codeword, the method further includes: performing symbol mapping and polarization distribution on 12 bits from four bit subsets in a second data stream that includes at least one codeword to obtain one DP-64QAM symbol, where the four bit subsets are respectively mapped, through Gray mapping, to an I component in an X polarization direction, a Q component in the X polarization direction, an I component in a Y polarization direction, and a Q component in the Y polarization direction that are of the DP-64QAM symbol, and the X polarization direction and the Y polarization direction are orthogonal to each other. In other words, any component of the DP-64QAM symbol is obtained by performing Gray mapping on three bits of one bit subset participating in the exclusive OR operation. Therefore, generally, at most one error bit occurs in three bits mapped to a same PAM8 symbol, thereby reducing a likelihood of an error bit.

In some possible implementations, the second FEC encoding is BCH encoding or extended BCH encoding over a finite field GF(2^{m}) with t-bit error correction, to enrich encoding modes that may be used for the inner encoding. mt≤p, and v+r≤2^{m}−1−p, that is, a value of m in GF(2^{m}) is not unique. For example, if the value of m is subtracted by 1 based on an original value, a quantity of parity bits may be reduced by t when encoding is performed in this manner, so that a bit rate of the codeword is increased and overheads of the codeword are reduced when a length of information bits is unchanged.

In some possible implementations, k=119, and GF(2^{m}) used in the second FEC encoding is GF(2⁸), GF(2⁷), or GF(2⁶). In a scenario in which k=119, implementability of the inner encoding is improved.

In some possible implementations, a length of the codeword is n, the second FEC encoding is the BCH encoding over GF(2^{m}) with t-bit error correction, and a correspondence among n, k, GF(2^{m}), t, and p is one of the following:

$$n = 131 , k = 119 , G F ( {2}^{m} ) = G F ( {2}^{6} ) , t = 2 , and p = 12 ;$$

$$n = 13 \; 3 , k = 119 , G F ( {2}^{m} ) = G F ( {2}^{7} ) , t = 2 , and p = 14 ; and$$

$$n = 13 \; 5 , k = 119 , G F ( {2}^{m} ) = G F ( {2}^{8} ) , t = 2 , and p = 16 .$$

In some possible implementations, a length of the codeword is n, the second FEC encoding is the extended BCH encoding over the finite field GF(2^{m}) with t-bit error correction, the p parity bits include a CRC extended check field of q bits, and a correspondence among n, k, GF(2^{m}), t, p, and q is one of the following:

$$n = 127 , k = 119 , G F ( {2}^{m} ) = G F ( {2}^{6} ) , t = 1 , p = 8 , and q = 2 ;$$

$$n = 12 \; 8 , k = 119 , G F ( {2}^{m} ) = G F ( {2}^{7} ) , t = 1 , p = 9 , and q = 2 ;$$

$$n = 13 \; 2 , k = 119 , G F ( {2}^{m} ) = G F ( {2}^{6} ) , t = 2 , p = 13 , and q = 1 ;$$

$$n = 13 \; 3 , k = 119 , G F ( {2}^{m} ) = G F ( {2}^{6} ) , t = 2 , p = 14 , and q = 2 ;$$

$$n = 13 \; 4 , k = 119 , G F ( {2}^{m} ) = G F ( {2}^{7} ) , t = 2 , p = 15 , and q = 1 ;$$

$$n = 13 \; 5 , k = 119 , G F ( {2}^{m} ) = G F ( {2}^{7} ) , t = 2 , p = 16 , and q = 2 ;$$

$$n = 13 \; 6 , k = 119 , G F ( {2}^{m} ) = G F ( {2}^{8} ) , t = 2 , p = 17 , and q = 1 ; and$$

$$n = 13 \; 7 , k = 119 , G F ( {2}^{m} ) = G F ( {2}^{8} ) , t = 2 , p = 18 , and q = 2 .$$

According to a third aspect, an embodiment of this disclosure provides a data encoding apparatus. The data encoding apparatus includes an obtaining unit and an encoding unit. The obtaining unit is configured to: obtain consecutive k bits in a first data stream obtained through first FEC encoding, where k is an odd number greater than 1, the consecutive k bits include a bit set and a target bit, the bit set includes (k−1)/2 bit subsets, and each bit subset includes two bits; and the encoding unit is configured to: perform inner encoding on the consecutive k bits to obtain a codeword, where the encoding unit is configured to: perform an exclusive OR operation on the two bits in each bit subset to obtain one bit, to obtain a total of (k−1)/2 bits; and perform second FEC encoding on a bit sequence that includes the (k−1)/2 bits and the target bit, to obtain p parity bits. The codeword obtained through inner encoding includes the consecutive k bits and the p parity bits, where p is an integer greater than or equal to 1.

In some possible implementations, the two bits in each bit subset are two adjacent bits in the consecutive k bits.

In some possible implementations, the p parity bits are located after the consecutive k bits in the codeword, and the target bit is a last bit in the consecutive k bits; or the p parity bits are located before the consecutive k bits in the codeword, and the target bit is a 1^{st} bit in the consecutive k bits.

In some possible implementations, the data encoding apparatus further includes a mapping unit, and the mapping unit is configured to: perform symbol mapping and polarization distribution on eight bits from four bit subsets in a second data stream that includes at least one codeword to obtain one DP-16QAM symbol, where the four bit subsets are respectively mapped to an I component in an X polarization direction, a Q component in the X polarization direction, an I component in a Y polarization direction, and a Q component in the Y polarization direction that are of the DP-16QAM symbol, and the X polarization direction and the Y polarization direction are orthogonal to each other.

In some possible implementations, the second FEC encoding is BCH encoding or extended BCH encoding over GF(2^{m}) with t-bit error correction, where both m and t are integers greater than or equal to 1, mt≤p, and

$$\frac{k + 1}{2} + p \leq {2}^{m} - 1 .$$

In some possible implementations, k=119, and GF(2^{m}) used in the second FEC encoding is GF(2⁸) or GF(2⁷).

In some possible implementations, a length of the codeword is n, the second FEC encoding is the BCH encoding over GF(2^{m}) with t-bit error correction, and a correspondence among n, k, GF(2^{m}), t, and p is one of the following:

$$n = 13 \; 3 , k = 119 , G F ( {2}^{m} ) = G F ( {2}^{7} ) , t = 2 , and p = 14 ; and$$

$$n = 135 , k = 119 , G F ( {2}^{m} ) = G F ( {2}^{8} ) , t = 2 , and p = 16 .$$

In some possible implementations, a length of the codeword is n, the second FEC encoding is the extended BCH encoding over the finite field GF(2^{m}) with t-bit error correction, the p parity bits include a CRC extended check field of q bits, and a correspondence among n, k, GF(2^{m}), t, p, and q is one of the following:

$$n = 12 \; 8 , k = 119 , G F ( {2}^{m} ) = G F ( {2}^{7} ) , t = 1 , p = 9 , and q = 2 ;$$

$$n = 134 , k = 119 , G F ( {2}^{m} ) = G F ( {2}^{7} ) , t = 2 , p = 15 , and q = 1 ;$$

$$n = 135 , k = 119 , G F ( {2}^{m} ) = G F ( {2}^{7} ) , t = 2 , p = 16 , and q = 2 ;$$

$$n = 136 , k = 119 , G F ( {2}^{m} ) = G F ( {2}^{8} ) , t = 2 , p = 17 , and q = 1 ; and$$

$$n = 137 , k = 119 , G F ( {2}^{m} ) = G F ( {2}^{8} ) , t = 2 , p = 18 , and q = 2 .$$

According to a fourth aspect, an embodiment of this disclosure provides a data encoding apparatus. The data encoding apparatus includes an obtaining unit and an encoding unit. The obtaining unit is configured to: obtain consecutive k bits in a first data stream obtained through first FEC encoding, where k is an integer greater than or equal to 3, the consecutive k bits include v bit subsets, each bit subset includes three bits, and v is an integer greater than or equal to 1; and the encoding unit is configured to: perform inner encoding on the consecutive k bits to obtain a codeword, where the encoding unit is configured to: perform an exclusive OR operation on the three bits in each bit subset to obtain one bit, to obtain a total of v bits; and perform second FEC encoding on a bit sequence that includes the v bits, to obtain p parity bits. The codeword obtained through inner encoding includes the consecutive k bits and the p parity bits, where p is an integer greater than or equal to 1.

In some possible implementations, the three bits in each bit subset are consecutive three bits in the consecutive k bits.

In some possible implementations, k=v×3.

In some possible implementations, the consecutive k bits further include r target bits, where k=v×3+r, and r=1 or 2, and the encoding unit is configured to: perform second FEC encoding on the bit sequence that includes the v bits and the r target bits, to obtain the p parity bits.

In some possible implementations, the p parity bits are located after the consecutive k bits in the codeword, and the target bits are last r bits in the consecutive k bits; or the p parity bits are located before the consecutive k bits in the codeword, and the target bits are first r bits in the consecutive k bits.

In some possible implementations, the data encoding apparatus further includes a mapping unit, and the mapping unit is configured to: perform symbol mapping and polarization distribution on 12 bits from four bit subsets in a second data stream that includes at least one codeword to obtain one DP-64QAM symbol, where the four bit subsets are respectively mapped to an I component in an X polarization direction, a Q component in the X polarization direction, an I component in a Y polarization direction, and a Q component in the Y polarization direction that are of the DP-64QAM symbol, and the X polarization direction and the Y polarization direction are orthogonal to each other.

In some possible implementations, the second FEC encoding is BCH encoding or extended BCH encoding over GF(2^{m}) with t-bit error correction, where both m and t are integers greater than or equal to 1, mt≤p, and v+r≤2^{m}−1−p.

In some possible implementations, k=119, and GF(2^{m}) used in the second FEC encoding is GF(2⁸), GF(2⁷), or GF(2⁶).

In some possible implementations, a length of the codeword is n, the second FEC encoding is the BCH encoding over GF(2^{m}) with t-bit error correction, and a correspondence among n, k, GF(2^{m}), t, and p is one of the following:

$$n = 13 \; 1 , k = 119 , G F ( {2}^{m} ) = G F ( {2}^{6} ) , t = 2 , and p = 12 ;$$

$$n = 133 , k = 119 , G F ( {2}^{m} ) = G F ( {2}^{7} ) , t = 2 , and p = 14 ; and$$

$$n = 135 , k = 119 , G F ( {2}^{m} ) = G F ( {2}^{8} ) , t = 2 , and p = 16 .$$

In some possible implementations, a length of the codeword is n, the second FEC encoding is the extended BCH encoding over the finite field GF(2^{m}) with t-bit error correction, the p parity bits include a CRC extended check field of q bits, and a correspondence among n, k, GF(2^{m}), t, p, and q is one of the following:

$$n = 12 \; 7 , k = 119 , G F ( {2}^{m} ) = G F ( {2}^{6} ) , t = 1 , p = 8 , and q = 2 ;$$

$$n = 128 , k = 119 , G F ( {2}^{m} ) = G F ( {2}^{7} ) , t = 1 , p = 9 , and q = 2 ;$$

$$n = 132 , k = 119 , G F ( {2}^{m} ) = G F ( {2}^{6} ) , t = 2 , p = 13 , and q = 1 ;$$

$$n = 133 , k = 119 , G F ( {2}^{m} ) = G F ( {2}^{6} ) , t = 2 , p = 14 , and q = 2 ;$$

$$n = 134 , k = 119 , G F ( {2}^{m} ) = G F ( {2}^{7} ) , t = 2 , p = 15 , and q = 1 ;$$

$$n = 135 , k = 119 , G F ( {2}^{m} ) = G F ( {2}^{7} ) , t = 2 , p = 16 , and q = 2 ;$$

$$n = 136 , k = 119 , G F ( {2}^{m} ) = G F ( {2}^{8} ) , t = 2 , p = 17 , and q = 1 ; and$$

$$n = 137 , k = 119 , G F ( {2}^{m} ) = G F ( {2}^{8} ) , t = 2 , p = 18 , and q = 2 .$$

According to a fifth aspect, an embodiment of this disclosure provides a chip. The chip includes a processor and a memory, the memory and the processor are connected to each other through a line, the memory stores instructions, and the processor is configured to perform the method described in any one of the implementations of the first aspect and the second aspect.

According to a sixth aspect, an embodiment of this disclosure provides a data transmission system. The data transmission system includes a data sending device and a data receiving device. The data sending device is configured to: perform the method described in any one of the implementations of the first aspect and the second aspect and send data to the data receiving device. The data receiving device is configured to perform an operation like decoding on the received data.

According to a seventh aspect, an embodiment of this disclosure provides a computer-readable storage medium, where the computer-readable storage medium stores a computer program, and when the computer program is executed by a computer, the method described in any one of the implementations of the first aspect and the second aspect is implemented.

### BRIEF DESCRIPTION OF DRAWINGS

FIG. 1 is a diagram of a communication system to which an embodiment of this disclosure is applied;

FIG. 2 is a diagram of another communication system to which an embodiment of this disclosure is applied;

FIG. 3 is a schematic flowchart of a data encoding method according to an embodiment of this disclosure;

FIG. 4A is a diagram of an implementation of performing an exclusive OR operation on every two bits according to an embodiment of this disclosure;

FIG. 4B is a diagram of another implementation of performing an exclusive OR operation on every two bits according to an embodiment of this disclosure;

FIG. 4C is a diagram of an implementation of performing an exclusive OR operation on every three bits according to an embodiment of this disclosure;

FIG. 5 is a diagram of an implementation of inner encoding according to an embodiment of this disclosure;

FIG. 6 is a diagram of a first application scenario of inner encoding according to an embodiment of this disclosure;

FIG. 7 is a diagram of a second application scenario of inner encoding according to an embodiment of this disclosure;

FIG. 8 is a diagram of a third application scenario of inner encoding according to an embodiment of this disclosure;

FIG. 9 is a diagram of a fourth application scenario of inner encoding according to an embodiment of this disclosure;

FIG. 10 is a diagram of a fifth application scenario of inner encoding according to an embodiment of this disclosure;

FIG. 11 is a diagram of a sixth application scenario of inner encoding according to an embodiment of this disclosure;

FIG. 12 is a diagram of a seventh application scenario of inner encoding according to an embodiment of this disclosure;

FIG. 13 is a diagram of a structure of a data encoding apparatus according to an embodiment of this disclosure; and

FIG. 14 is a diagram of another structure of a data encoding apparatus according to an embodiment of this disclosure.

### DESCRIPTION OF EMBODIMENTS

Embodiments of this disclosure provide a data encoding method and a related apparatus, to reduce encoding complexity without changing a length of an inner codeword and redundancy costs. It should be noted that in the specification, claims, and the foregoing accompanying drawings of this disclosure, the terms “first”, “second”, and the like are intended to distinguish similar objects but do not limit a specific order or sequence. It should be understood that the foregoing terms may be interchanged in proper cases, so that embodiments described in this disclosure can be implemented in other orders than the order in the content described in this disclosure. In addition, the terms “include”, “have”, and any other variant thereof are intended to cover a non-exclusive inclusion. For example, a process, method, system, product, or device that includes a list of steps or units is not necessarily limited to those expressly enumerated steps or units, but may include other steps or units not expressly enumerated or inherent to such a process, method, product, or device.

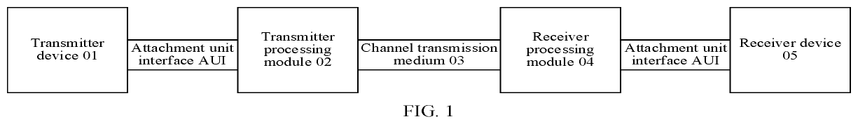

FIG. 1 is a diagram of a communication system to which an embodiment of this disclosure is applied. As shown in FIG. 1, the communication system includes a transmitter device 01, a transmitter processing module 02, a channel transmission medium 03, a receiver processing module 04, and a receiver device 05. For example, the communication system is a data center network. The transmitter device 01 and the receiver device 05 may be devices such as a switch or a router, the transmitter device 01 is also referred to as a host chip located at a transmitter, the receiver device 05 is also referred to as a host chip located at a receiver, and the channel transmission medium 03 may be an optical fiber. The host chip is also sometimes referred to as a host device. The transmitter device 01 may be connected to the transmitter processing module 02 through an attachment unit interface (AUI), and the receiver device 05 may be connected to the receiver processing module 04 through an AUI. The transmitter processing module 02 and the receiver processing module 04 may each be an optical module, an electrical module, a connector, or another module that processes data in a data sending process. For example, the processing module may be an 800ZR module, which is a coherent optical module. In addition, all the transmitter device 01, the transmitter processing module 02, the channel transmission medium 03, the receiver processing module 04, and the receiver device 05 in the communication system may support bidirectional transmission or unidirectional transmission. This is not limited herein.

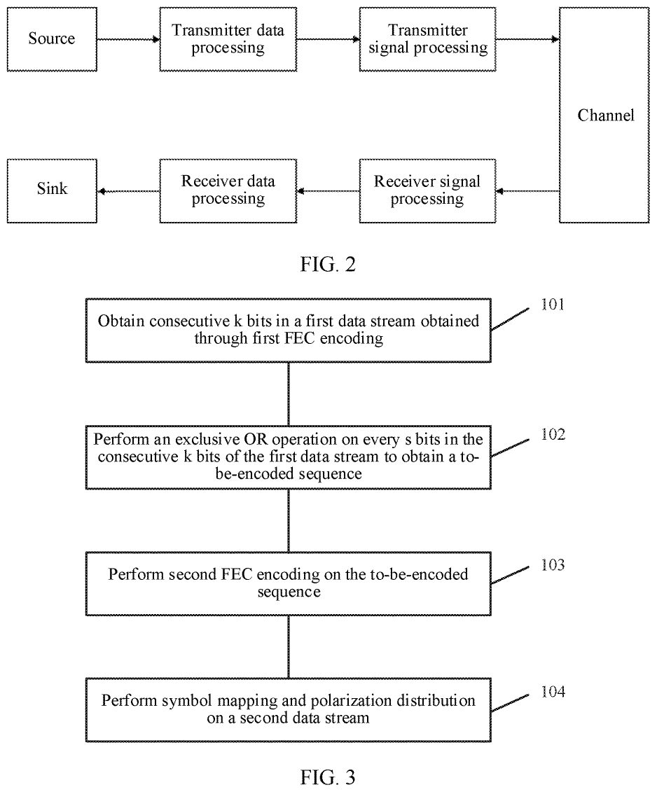

FIG. 2 is a diagram of another communication system to which an embodiment of this disclosure is applied. As shown in FIG. 2, at a transmitter, a source provides a to-be-sent data stream. A transmitter data processor receives the data stream, performs data processing including encoding, interleaving, and modulation on the data stream to obtain a symbol data stream. The symbol data stream is then delivered to a transmitter signal processor for framing and is transmitted through a channel to a receiving device. After receiving a signal that is distorted due to noise or other impairments on the channel, the receiving device sends the signal to a receiver signal processor for dispersion compensation, synchronization, phase recovery, and other operations. Then, the signal is sent to the receiver data processing for performing demodulation, de-interleaving, and decoding, to recover original data, and send the data to a sink. Transmitter data processing and transmitter signal processing shown in FIG. 2 may be applied to the transmitter processing module 02 shown in FIG. 1, and receiver data processing and receiver signal processing shown in FIG. 2 may be applied to the receiver processing module 04 shown in FIG. 1.

It should be understood that the “inner” in an inner code and the “outer” in an outer code are distinguished based merely on a distance between an execution body that performs an operation on data and a channel transmission medium. An execution body that performs an operation on the inner code is closer to the channel transmission medium, and an execution body that performs an operation on the outer code is farther away from the channel transmission medium. In embodiments of this disclosure, FIG. 1 is used as an example. Because the transmitter processing module 02 sequentially encodes data twice and then sends the encoded data to the channel transmission medium, data that is first encoded by the transmitter processing module 02 is farther away from the channel transmission medium, and data that is later encoded by the transmitter processing module 02 is closer to the channel transmission medium. In this way, the data that is first encoded by the transmitter processing module 02 is referred to as outer encoded data, and the data that is later encoded by the transmitter processing module 02 is referred to as inner encoded data. Correspondingly, data that is first decoded by the receiver processing module 04 is referred to as inner decoded data, and data that is later decoded by the receiver processing module 04 is referred to as outer decoded data. In a possible implementation, both the inner encoding and the outer encoding use an FEC encoding manner, so as to form a concatenated FEC transmission scheme. For example, the transmitter processing module 02 may perform outer encoding by using a staircase code, perform inner encoding by using a Hamming code, or perform inner encoding by using a BCH code.

It should be noted that the foregoing content is example description of an application scenario of the data encoding method provided in embodiments of this disclosure, and does not constitute any limitation on application scenarios of the data encoding method. A person of ordinary skill in the art may learn that, as a service requirement changes, the application scenario of the data encoding method may be adjusted based on an application requirement. Application scenarios are not listed one by one in embodiments of this disclosure. The following mainly describes a data encoding method applied to a data transmitter. A data decoding method applied to a receiver may be understood as an inverse operation of the data encoding method. With the encoding method determined, the data decoding method is also clear. Therefore, the data decoding method is not described in detail in this disclosure.

FIG. 3 is a schematic flowchart of a data encoding method according to an embodiment of this disclosure. The data encoding method includes the following steps, which are described in detail below. It should be understood that, for ease of description, first FEC encoding in the following is equivalent to the outer encoding described above. Inner encoding provided in embodiments of this disclosure includes two operations: grouping and exclusive OR and second FEC encoding. The following may be understood based on this.
101: Obtain consecutive k bits in a first data stream obtained through first FEC encoding.

In embodiments of this disclosure, the consecutive k bits in the first data stream are k information bits on which inner encoding is to be performed. It should be understood that, for an inner code, the k information bits on which inner encoding is to be performed may include an information bit and a parity bit in an outer codeword. Considering that the inner encoding is mainly described in embodiments of this disclosure, all information bits appearing in the following may be understood as information bits of the inner encoding. It should be further understood that a specific implementation of the outer encoding is not limited in this disclosure. In an example, the outer encoding may be staircase (512, 510) encoding.
102: Perform an exclusive OR operation on every s bits in the consecutive k bits of the first data stream to obtain a to-be-encoded sequence.

It should be understood that, in an inner codeword obtained through inner code encoding, consecutive s bits are mapped to one symbol through Gray mapping and sent to a channel for transmission. Therefore, under a non-extreme channel condition, only one bit error occurs in the consecutive s bits. A symbol mapping manner includes but is not limited to quadrature phase shift keying (QPSK) and QAM, and then polarization symbol distribution is performed to obtain a DP symbol, for example, DP-QPSK, DP-8QAM, DP-16QAM, DP-32QAM, and DP-64QAM. In an example, when DP-16QAM is used, consecutive two bits in the inner codeword are mapped to a same PAM4 symbol. In another example, when DP-64QAM is used, consecutive three bits in the inner codeword are mapped to a same PAM8 symbol. Therefore, in embodiments of this disclosure, it is considered that an exclusive OR operation is first performed on every two or three bits in the consecutive k bits of the first data stream, and then encoding is performed. The following uses k=119 as an example to describe several possible exclusive OR operation manners.

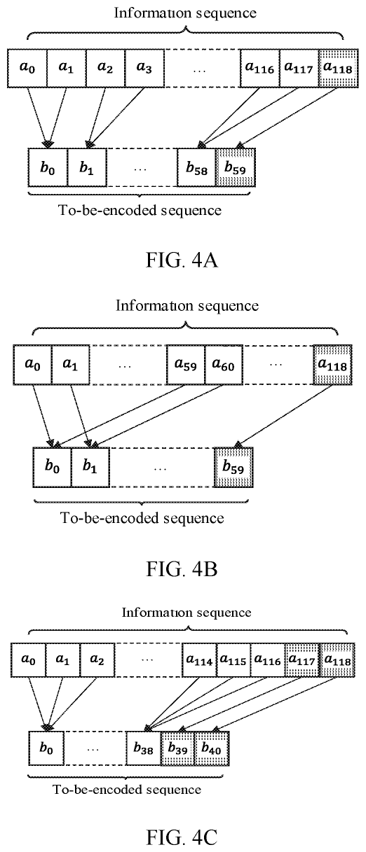

FIG. 4A is a diagram of an implementation of performing an exclusive OR operation on every two bits according to an embodiment of this disclosure. As shown in FIG. 4A, in a possible implementation, because 119 is an odd number, one bit in an information sequence including 119 bits cannot undergo a pairwise exclusive OR operation, and the bit is referred to as a target bit herein. It should be understood that the target bit may be any bit in the information sequence. Generally, the target bit is a 1^{st} bit or a last bit in the information sequence. For example, as shown in FIG. 4A, the target bit is a last bit a₁₁₈ in the information sequence. For ease of description, the remaining 118 bits in the information sequence other than the target bit are referred to as a bit set herein. The bit set includes 59 bit subsets, and each bit subset includes two bits. Further, an exclusive OR operation is performed on the two bits in each bit subset to obtain one bit, so as to obtain a total of 59 bits, as shown in b₀ to b₅₈ in FIG. 4A. In this implementation, the two bits in each bit subset are two adjacent bits in the 119-bit information sequence. As shown in FIG. 4A, an exclusive OR operation is performed on a₀ and a₁ to obtain b₀, an exclusive OR operation is performed on a₂ and a₃ to obtain b₁, . . . , and an exclusive OR operation is performed on a₁₁₆ and a₁₁₇ to obtain b₅₈. Further, the target bit a₁₁₈ in the information sequence is used as one bit b₅₉ in the to-be-encoded sequence, and the to-be-encoded sequence includes b₀ to b₅₈ that are obtained through exclusive OR operations and b₅₉.

FIG. 4B is a diagram of another implementation of performing an exclusive OR operation on every two bits according to an embodiment of this disclosure. Different from the implementation shown in FIG. 4A, in another possible implementation, the two bits in each bit subset may alternatively be any two non-adjacent bits in a 119-bit information sequence. A specific manner is not limited herein. For example, as shown in FIG. 4B, an exclusive OR operation is performed on a₀ and a₅₉ to obtain b₀, an exclusive OR operation is performed on a₁ and a₆₀ to obtain b₁, . . . , and an exclusive OR operation is performed on a₅₈ and a₁₁₇ to obtain b₅₈. Further, the target bit a₁₁₈ in the information sequence is used as one bit b₅₉ in the to-be-encoded sequence, and the to-be-encoded sequence includes b₀ to b₅₈ that are obtained through exclusive OR operations and b₅₉.

It should be noted that, based on the 2-bit exclusive OR operation implementations shown in FIG. 4A and FIG. 4B, a specific value of k is not limited in this disclosure. If k is an odd number greater than 1, one target bit in an information sequence including the k bits definitely does not participate in the exclusive OR operation. If k is an even number, an exclusive OR operation can be exactly performed on every two bits of all the k bits in the information sequence.

FIG. 4C is a diagram of an implementation of performing an exclusive OR operation on every three bits according to an embodiment of this disclosure. As shown in FIG. 4C, in still another possible implementation, because a remainder of 119 divided by 3 is 2, two bits in an information sequence including 119 bits cannot undergo a 3-bit exclusive OR operation, and the two bits are referred to as target bits herein. It should be understood that the two target bits may be any two bits in the information sequence. Generally, the two target bits are first two bits or last two bits in the information sequence. For example, as shown in FIG. 4C, the two target bits are last two bits a₁₁₇ and a₁₁₈ in the information sequence. For ease of description, the remaining 117 bits in the information sequence other than the target bits are referred to as a bit set herein. The bit set includes 39 bit subsets, and each bit subset includes three bits. Further, an exclusive OR operation is performed on the three bits in each bit subset to obtain one bit, so as to obtain a total of 39 bits, as shown in b₀ to b₃₈ in FIG. 4C. In this implementation, the three bits in each bit subset are consecutive three bits in the 119-bit information sequence. As shown in FIG. 4C, an exclusive OR operation is performed on a₀, a₁, and a₂ to obtain b₀, . . . , and an exclusive OR operation is performed on a₁₁₄, a₁₁₅, and a₁₁₆ to obtain b₃₈. Further, the target bits a₁₁₇ and a₁₁₈ in the information sequence are used as two bits b₃₉ and b₄₀ in the to-be-encoded sequence, and the to-be-encoded sequence includes b₀ to b₃₈ that are obtained through exclusive OR operations, b₃₉, and b₄₀.

It should be noted that, based on the 3-bit exclusive OR operation implementation shown in FIG. 4C, a specific value of k is not limited in this disclosure. For example, k may alternatively be exactly an integer multiple of 3, and 3-bit exclusive OR operations may be exactly performed on all the k bits in the information sequence. For another example, a remainder of k divided by 3 may alternatively be 1, and in this case, one bit in the k bits of the information sequence is a target bit that does not participate in the exclusive OR operation, and 3-bit exclusive OR operations may be performed on other bits than the target bit.
103: Perform second FEC encoding on the to-be-encoded sequence.

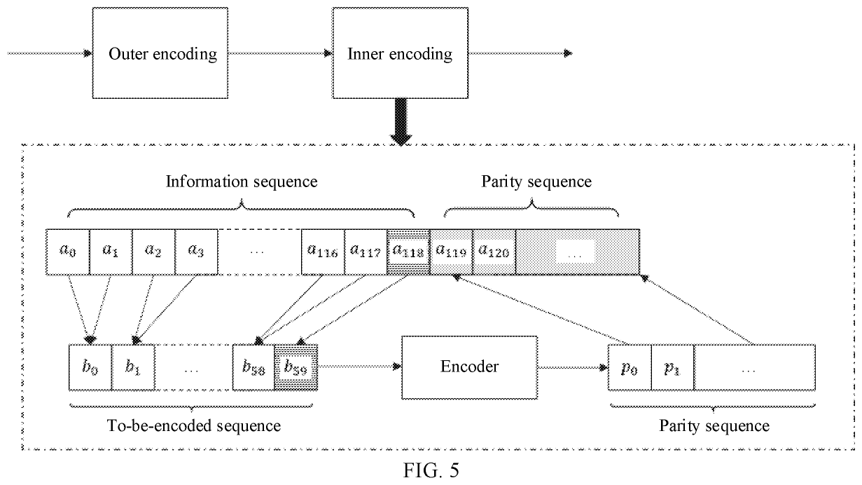

FIG. 5 is a diagram of an implementation of inner encoding according to an embodiment of this disclosure. As shown in FIG. 5, the to-be-encoded sequence is a bit sequence on which the second FEC encoding is to be performed. The to-be-encoded sequence includes the bit obtained through the exclusive OR operation in step 102. Based on this, the to-be-encoded sequence may further include the target bit that does not participate in the exclusive OR operation. A specific case depends on a value of k. For details, refer to related descriptions in step 102. k=119 is used as an example herein. The second FEC encoding is performed on the to-be-encoded sequence to obtain a parity sequence including p parity bits. For the inner codeword obtained through inner encoding, the inner codeword includes the information sequence of the k bits and the p parity bits, that is, a length n of the inner codeword is n=k+p, where p is an integer greater than or equal to 1. That is, the second FEC encoding performed on the to-be-encoded sequence is only for generating the parity sequence, and the inner codeword obtained through encoding still includes the information sequence including the k bits. For example, if the target bit is a last bit in the to-be-encoded sequence, the parity sequence in the inner codeword is located after the information sequence. For another example, if the target bit is a 1^{st} bit in the to-be-encoded sequence, the parity sequence in the inner codeword is located before the information sequence. It should be noted that the second FEC encoding may be BCH encoding or extended BCH encoding. p parity bits in an inner codeword obtained through the BCH encoding do not include a CRC extended parity bit, while p parity bits in an inner codeword obtained through the extended BCH encoding include a 1-bit or 2-bit CRC extended check field.

In a possible implementation, for a 2-bit exclusive OR operation encoding scheme and a 3-bit exclusive OR operation encoding scheme, the second FEC encoding may be BCH encoding over GF(2^{m}) with t-bit error correction, where both m and t are integers greater than or equal to 1. GF refers to a finite field, or may be referred to as a Galois field, and 2^{m} represents an order of the finite field. An error correction capability of the second FEC encoding is t bits, that is, one inner codeword can be used to correct a maximum of t bits. If the P parity bits do not include a CRC extended check field, p=m×t; if the P parity bits include the 1-bit CRC extended check field, p=m×t+1; or if the P parity bits include the 2-bit CRC extended check field, p=m×t+2.

In another possible implementation, for a 2-bit exclusive OR operation encoding scheme, if

$$\frac{k + 1}{2} \leq {2}^{m - 1} - 1 - p ,$$

the second FEC encoding may alternatively use a BCH codeword over GF(2^{m-1}) to further simplify an inner encoding scheme. If the P parity bits do not include a CRC extended check field, p=(m−1)×t; if the P parity bits include the 1-bit CRC extended check field, p=(m−1)×t+1; or if the P parity bits include the 2-bit CRC extended check field, p=(m−1)×t+2. It should be understood that, when the second FEC encoding is the BCH encoding over GF(2^{m}), a length of the inner codeword is denoted as n0, or when the second FEC encoding uses the BCH codeword over GF(2^{m-1}), a length of the inner codeword is denoted as n1, where n0=k+(m−1)t=n1−t. In this case, an original (n0, k) codeword is replaced with a (n1, k) codeword. That is, a quantity of parity bits may be reduced by t when encoding is performed in this manner, so that a bit rate of the codeword is increased and overheads of the codeword are reduced when a length of information is unchanged.

In still another possible implementation, for a 3-bit exclusive OR operation encoding scheme, the k bits include v bit subsets, each bit subset includes three bits, v is an integer greater than or equal to 1, and a quantity of CRC extended check fields included in the p parity bits is denoted as r. If v+r≤2^{m-1}−1−p, the second FEC encoding may alternatively use a BCH codeword over GF(2^{m-1}) to further simplify an inner encoding scheme. If the P parity bits do not include the CRC extended check field, p=(m−1)×t; if the P parity bits include the 1-bit CRC extended check field, p=(m−1)*t+1; or if the P parity bits include the 2-bit CRC extended check field, p=(m−1)×t+2. If v+r≤2^{m-2}−1−p, the second FEC encoding may alternatively use a BCH codeword over GF(2^{m-2}) to further simplify an inner encoding scheme. If the P parity bits do not include the CRC extended check field, p=(m−2)×t; if the P parity bits include the 1-bit CRC extended check field, p=(m−2)×t+1; or if the P parity bits include the 2-bit CRC extended check field, p=(m−2)*t+2.
104: Perform symbol mapping and polarization distribution on a second data stream.

It should be understood that the second data stream includes at least one inner codeword obtained through inner encoding. In an example, for the 2-bit exclusive OR operation encoding scheme, symbol mapping and polarization distribution are performed on every eight bits in the second data stream to obtain one DP-16QAM symbol. The eight bits participating in symbol mapping and polarization distribution are from four-bit subsets that participate in exclusive OR operations and that are in the information sequence. In another example, for the 3-bit exclusive OR operation encoding scheme, symbol mapping and polarization distribution are performed on every 12 bits in the second data stream to obtain one DP-64QAM symbol. The 12 bits participating in symbol mapping and polarization distribution are from four-bit subsets that participate in exclusive OR operations and that are in the information sequence. It should be understood that the four bit subsets are respectively mapped to an I (in-phase) component in an X-polarization direction, a Q (quadrature-phase) component in the X-polarization direction, an I (in-phase) component in a Y-polarization direction, and a Q (quadrature-phase) component in the Y-polarization direction that are of the DP-16QAM symbol or the DP-64QAM symbol. The X polarization direction and the Y polarization direction are orthogonal to each other. In other words, any component of the DP-16QAM symbol is obtained by mapping two bits of one bit subset participating in the exclusive OR operation, and any component of the DP-64QAM symbol is obtained by mapping three bits of one bit subset participating in the exclusive OR operation. It should be further understood that the four bit subsets mapped to the DP-16QAM symbol or the DP-64QAM symbol may come from a same codeword, or may come from different codewords. This is not limited herein.

It should be noted that an example in which a length of the information sequence of the inner codeword is 119 bits is used. Based on this, embodiments of this disclosure provide a plurality of possible inner encoding parameters. When a DP-16QAM scheme is used, details are shown in Table 1 below, or when a DP-64QAM scheme is used, details are shown in Table 2 below. n represents the length of the inner codeword, k represents the length of the information sequence of the inner codeword, w represents an encoding length (including the to-be-encoded sequence and the parity sequence), f represents a length of the to-be-encoded sequence, and GF(2^{m}) represents a finite field. t indicates an error correction capability of the inner encoding. OH represents overheads of the inner codeword, and means a proportion of a length of the parity sequence in the inner codeword to the length of the information sequence, that is, OH=(n−k)/k. “No extension” in the remarks means that there is no CRC extended check field in the parity sequence, “single-bit extension” in the remarks means that there is a 1-bit CRC extended check field in the parity sequence, and “double-bit extension” in the remarks means that there is a 2-bit CRC extended check field in the parity sequence.

TABLE 1

| Scheme | n | k | p | w | f | GF(2^{m}) | t | OH | Remarks |
|---|---|---|---|---|---|---|---|---|---|
| 1 | 128 | 119 | 9 | 69 | 60 | GF(2⁷) | 1 | 7.6% | Double-bit extension |
| 2 | 133 | 119 | 14 | 74 | 60 | GF(2⁷) | 2 | 11.8% | No extension |
| 3 | 134 | 119 | 15 | 75 | 60 | GF(2⁷) | 2 | 12.6% | Single-bit extension |
| 4 | 135 | 119 | 16 | 76 | 60 | GF(2⁷) | 2 | 13.4% | Double-bit extension |
| 5 | 135 | 119 | 16 | 76 | 60 | GF(2⁸) | 2 | 13.4% | No extension |
| 6 | 136 | 119 | 17 | 77 | 60 | GF(2⁸) | 2 | 14.2% | Single-bit extension |
| 7 | 137 | 119 | 18 | 78 | 60 | GF(2⁸) | 2 | 15.1% | Double-bit extension |

For the schemes provided in Table 1, the scheme 1 is a codeword defined over a finite field GF(2⁷) with an error correction capability t=1, and encoding and decoding complexity can be reduced in another technology by using an exclusive OR manner. In schemes 5 to 7, a codeword actually encoded is based on systematic BCH (255, 239) codeword over a finite field GF(2⁸) with t=2, and after the codeword is shortened by 179 bits, a BCH (76, 60) codeword actually encoded in the scheme 5 is obtained, which has a stronger coding gain in comparison with that in scheme 1. Based on the scheme 5, a single-bit CRC extended check field and a double-bit CRC extended check field are separately added, to obtain a BCH (77, 60) codeword actually encoded in the scheme 6 and a BCH (78, 60) codeword actually encoded in the scheme 7, and a coding gain may be further improved based on the scheme 5. In schemes 2 to 4, a codeword actually encoded is based on system BCH (127, 113) over a finite field GF(2⁷) with t=2, and after the codeword is shortened by 53 bits, a BCH (74, 60) codeword actually encoded in the scheme 2 is obtained. Based on the scheme 2, a single-bit CRC extended check field and a double-bit CRC extended check field are separately added, to obtain a BCH (75, 60) codeword actually encoded in the scheme 3 and a BCH (76, 60) codeword actually encoded in the scheme 4. Compared with the schemes 5 to 7, the schemes 2 to 4 satisfy the foregoing mentioned relationship:

$$\frac{k + 1}{2} \leq {2}^{m - 1} - 1 - p ,$$

and therefore, the original finite field GF(2⁸) may be replaced with the low-complexity finite field GF(2⁷).

TABLE 2

| Scheme | n | k | p | w | f | GF(2^{m}) | t | OH | Remarks |
|---|---|---|---|---|---|---|---|---|---|
| 1 | 127 | 119 | 8 | 49 | 41 | GF(2⁶) | 1 | 6.7% | Double-bit extension |
| 2 | 128 | 119 | 9 | 50 | 41 | GF(2⁷) | 1 | 7.6% | Double-bit extension |
| 3 | 131 | 119 | 12 | 53 | 41 | GF(2⁶) | 2 | 10.1% | No extension |
| 4 | 132 | 119 | 13 | 54 | 41 | GF(2⁶) | 2 | 10.9% | Single-bit extension |
| 5 | 133 | 119 | 14 | 55 | 41 | GF(2⁶) | 2 | 11.8% | Double-bit extension |
| 6 | 133 | 119 | 14 | 55 | 41 | GF(2⁷) | 2 | 11.8% | No extension |
| 7 | 134 | 119 | 15 | 56 | 41 | GF(2⁷) | 2 | 12.6% | Single-bit extension |
| 8 | 135 | 119 | 16 | 57 | 41 | GF(2⁷) | 2 | 13.4% | Double-bit extension |
| 9 | 135 | 119 | 16 | 57 | 41 | GF(2⁸) | 2 | 13.4% | No extension |
| 10 | 136 | 119 | 17 | 58 | 41 | GF(2⁸) | 2 | 14.2% | Single-bit extension |
| 11 | 137 | 119 | 18 | 59 | 41 | GF(2⁸) | 2 | 15.1% | Double-bit extension |

For the schemes provided in Table 2, scheme 1 and scheme 2 use a Hamming code defined over a finite field GF(2⁶) with an error correction capability t=1 and a Hamming code defined over a finite field GF(2⁷), respectively, each with an error correction capability t=1, schemes 3 to 5 use BCH codes over a finite field GF(2⁶) with an error correction capability t=2, schemes 6 to 8 use BCH codes over a finite field GF(2⁷) with an error correction capability t=2, and candidate schemes 9 to 11 use BCH codes over a finite field GF(2⁸) with an error correction capability t=2.

It should be noted that, in some possible scenarios, an inner encoding scheme in a DP-16QAM modulation scheme may be compatible with an inner encoding scheme in a DP-64QAM modulation scheme. Table 3 below provides parameters compatible with inner encoding of both modulation schemes. In actual application, encoders corresponding to the two modulation schemes may be integrated together, for flexible selection based on an actual requirement.

TABLE 3

| | | | | w | f | w | f | | |
|---|---|---|---|---|---|---|---|---|---|
| Scheme | n | k | p | (16QAM) | (16QAM) | (64QAM) | (64QAM) | GF(2^{m}) | Remarks |
| 1 | 128 | 119 | 9 | 69 | 60 | 50 | 41 | GF(2⁷) | Double-bit extension |
| 2 | 133 | 119 | 14 | 74 | 60 | 55 | 41 | GF(2⁷) | No extension |
| 3 | 134 | 119 | 15 | 75 | 60 | 56 | 41 | GF(2⁷) | Single-bit extension |
| 4 | 135 | 119 | 16 | 76 | 60 | 57 | 41 | GF(2⁷) | Double-bit extension |
| 5 | 135 | 119 | 16 | 76 | 60 | 57 | 41 | GF(2⁸) | No extension |
| 6 | 136 | 119 | 17 | 77 | 60 | 58 | 41 | GF(2⁸) | Single-bit extension |
| 7 | 137 | 119 | 18 | 78 | 60 | 59 | 41 | GF(2⁸) | Double-bit extension |

The following describes several specific inner encoding embodiments based on parameters of the inner encoding.

### Embodiment 1: In a DP-16QAM Modulation Scheme, Inner Encoding is (128, 119) with (69, 60) Over GF(2⁷) Encoding

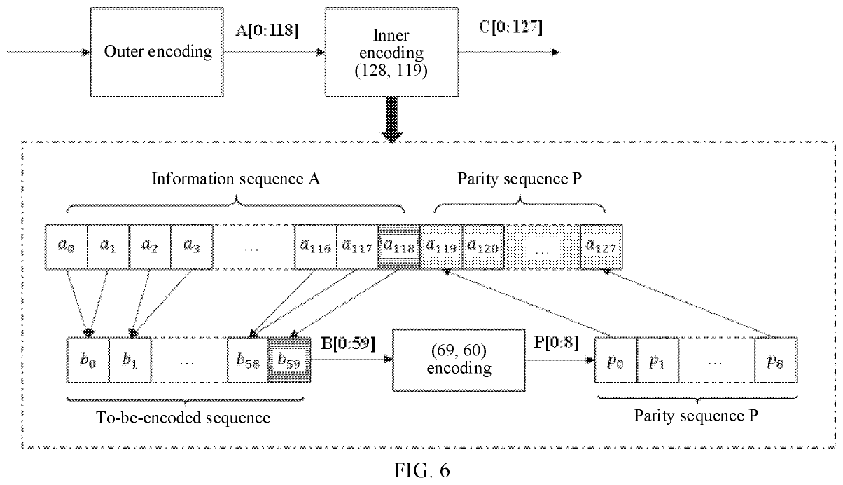

FIG. 6 is a diagram of a first application scenario of inner encoding according to an embodiment of this disclosure. As shown in FIG. 6, a length of an inner encoded codeword is 128 bits, where a length of an information sequence is 119 bits, and a length of a parity sequence is 9 bits. First, 118 bits are selected from the 119-bit information sequence A to form a sequence A′, and are denoted as

$${A}^{′} = [ {a}_{0}^{′} , {a}_{1}^{′} , … , {a}_{117}^{′} ] .$$

A′ may be any 118 bits in A. To facilitate subsequent channel interleaving and modulation, first 118 bits in A may be selected as A′, that is, A′ [a₀, a₁, . . . , a₁₁₇]. Then, two adjacent bits in A′ are grouped into one group to perform an exclusive OR operation, so as to obtain 59 bits [b₀, b₁, . . . , b₅₈]. In addition, a bit in A that is not selected into A′ is denoted as A\A′, a grouping and exclusive OR operation is skipped for A\A′, and A\A′ is combined with b₀~b₅₈ to form a to-be-encoded sequence B[0:59]=[b₀, b₁, . . . , b₅₉], which is expressed as follows:

$$\{ \begin{matrix}{b}_{i} = {a}_{21}^{′} \hat{} {a}_{2 i + 1}^{′} , i ∈ [ 0 , 58 ] \\ {b}_{i} = A \backslash {A}^{′} , i = 59\end{matrix} .$$

Then, extended Hamming code (69, 60) encoding is performed on the to-be-encoded sequence to generate a 9-bit parity bit [p₀, p₁, . . . , p₈]. An extended Hamming code (69, 60) is obtained by shortening, by 59 bits, a double-bit extended Hamming code constructed over a finite field GF(2⁷). Finally, a codeword C[0:127]=[c₀, c₁, . . . , c₁₂₇] generated by inner encoding (128, 119) may be represented as

$$\{ \begin{matrix}{c}_{i} = {a}_{i} , & i ∈ [ 0 , 118 ] \\ {c}_{i} = {p}_{i - 119} , & i ∈ [ 119 , 127 ]\end{matrix} .$$

It should be understood that, in the foregoing process, soft-decision FEC (SD-FEC) (128, 119) is still a system code, that is, (69, 60) encoding is only used for generating a parity bit, and does not participate in actual transmission.

### Embodiment 2: In a DP-16QAM Modulation Scheme, Inner Encoding is (133, 119) with (74, 60) Over GF(2⁷) Encoding

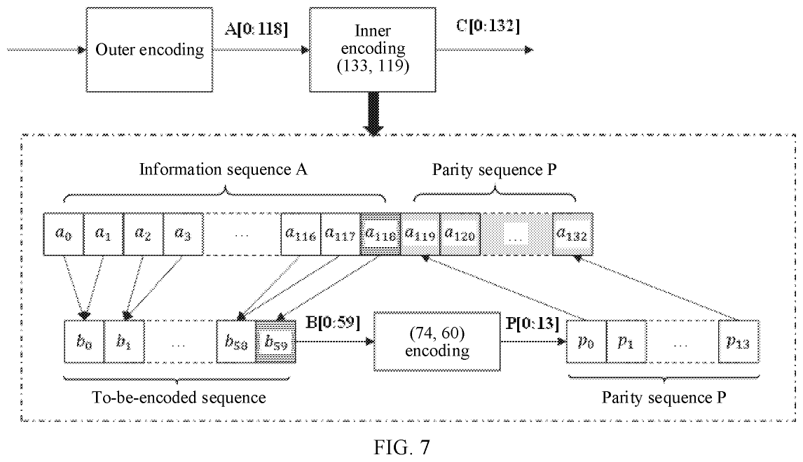

FIG. 7 is a diagram of a second application scenario of inner encoding according to an embodiment of this disclosure. As shown in FIG. 7, a length of an inner encoded codeword is 133 bits, where a length of an information sequence is 119 bits, and a length of a parity sequence is 14 bits. First, a to-be-encoded sequence B[0:59] is generated based on an information sequence A[0:118] in a manner the same as that in Embodiment 1. Then, BCH (74, 60) encoding is performed on the to-be-encoded sequence to generate a 14-bit parity bit [p₀, p₁, . . . , p₁₃]. BCH (74, 60) is obtained by shortening, by 53 bits, BCH (127, 113) constructed over a finite field GF(2⁷) with t=2. A generator polynomial of the BCH (74, 60) over GF(2⁷) may be expressed as:

$$g ( x ) = M 1 ( x ) M 3 ( x ) = ( {x}^{7} + {x}^{3} + 1 ) ( {x}^{7} + {x}^{3} + {x}^{2} + x + 1 ) = {x}^{14} + {x}^{9} + {x}^{8} + {x}^{6} + {x}^{5} + {x}^{4} + {x}^{2} + x + 1$$

M1(x) and M3(x) respectively correspond to minimum polynomials of α¹ and α³, and α is a primitive element of the finite field GF(2⁷). 60 bits to be encoded are respectively used as coefficients of a polynomial with a highest degree of 59, to obtain an information polynomial m(x). A remainder polynomial r(x) is obtained, using modulo-2 division, by dividing x¹⁴m(x) by g(x), and coefficients of items in r(x) are a parity sequence P[0:13]. Finally, the information sequence A and the parity sequence P form a complete codeword of inner encoding (133, 119), which is denoted as C[0:132]=[c₀, c₁, . . . , c₁₃₂] and may be represented as

$$\{ \begin{matrix}{c}_{i} = {a}_{i} , & i ∈ [ 0 , 118 ] \\ {c}_{i} = {p}_{i - 119} , & i ∈ [ 119 , 132 ]\end{matrix} .$$

### Embodiment 3: In a DP-16QAM Modulation Scheme, Inner Encoding is (134, 119) with (75, 60) Over GF(2⁷) Encoding

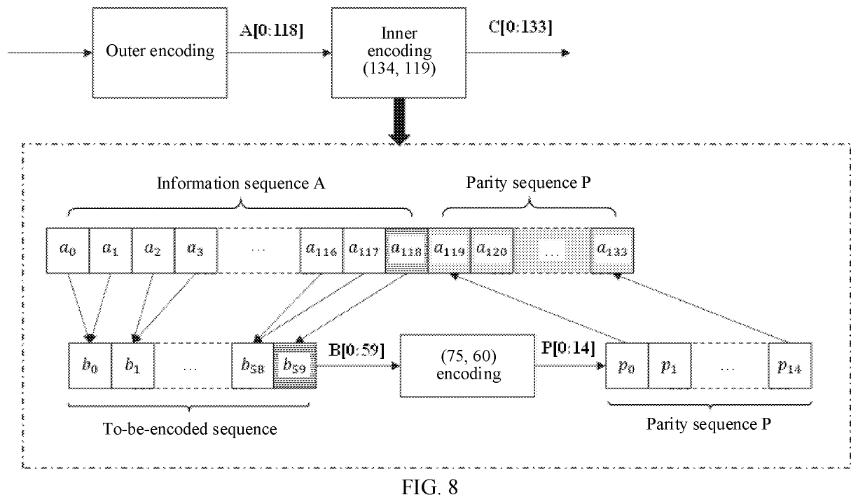

FIG. 8 is a diagram of a third application scenario of inner encoding according to an embodiment of this disclosure. As shown in FIG. 8, a length of an inner encoded codeword is 134 bits, where a length of an information sequence is 119 bits, and a length of a parity sequence is 15 bits. First, a to-be-encoded sequence B[0:59] is generated based on an information sequence A[0:118] in a manner the same as that in Embodiment 1. Then, extended BCH (75, 60) encoding is performed on the to-be-encoded sequence to generate a 15-bit parity bit [p₀, p₁, . . . , p₁₄]. Extended BCH (75, 60) is obtained by adding single-bit parity check based on the BCH (74, 60) in Embodiment 2. A generator polynomial of the extended BCH (75, 60) over GF(2⁷) may be expressed as:

$$g 1 ( x ) = g ( x ) ( x + 1 ) = ( {x}^{7} + {x}^{3} + 1 ) ( {x}^{7} + {x}^{3} + {x}^{2} + x + 1 ) ( x + 1 ) = {x}^{15} + {x}^{14} + {x}^{10} + {x}^{8} + {x}^{7} + {x}^{4} + {x}^{3} + 1$$

60 bits to be encoded are respectively used as coefficients of a polynomial with a highest degree of 59, to obtain an information polynomial m(x). A remainder polynomial r(x) is obtained, using modulo-2 division, by dividing x¹⁵m(x) by g1(x), and coefficients of items in r(x) are a parity sequence P[0:14]. Finally, the information sequence A and the parity sequence P form a complete codeword of inner encoding (134, 119), which is denoted as C[0:133]=[c₀, c₁, . . . , c₁₃₃] and may be represented as

$$\{ \begin{matrix}{c}_{i} = {a}_{i} , & i ∈ [ 0 , 118 ] \\ {c}_{i} = {p}_{i - 119} , & i ∈ [ 119 , 133 ]\end{matrix} .$$

### Embodiment 4: In a DP-16QAM Modulation Scheme, Inner Encoding is (135, 119) with (76, 60) Over GF(2⁷) Encoding

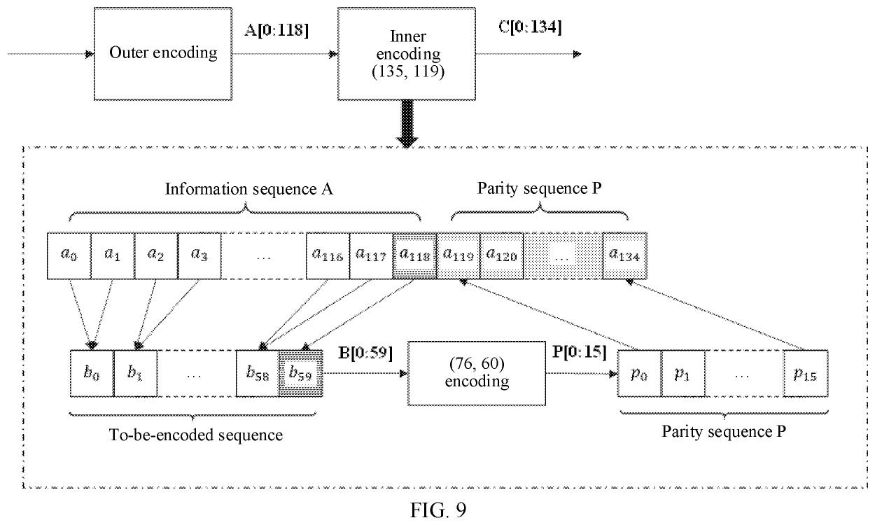

FIG. 9 is a diagram of a fourth application scenario of inner encoding according to an embodiment of this disclosure. As shown in FIG. 9, a length of an inner encoded codeword is 135 bits, where a length of an information sequence is 119 bits, and a length of a parity sequence is 16 bits. First, a to-be-encoded sequence B[0:59] is generated based on an information sequence A[0:118] in a manner the same as that in Embodiment 1. Then, extended BCH (76, 60) encoding is performed on the to-be-encoded sequence to generate a 16-bit parity bit [p₀, p₁, . . . , p₁₅]. Extended BCH (76, 60) is obtained by adding double-bit parity check based on the BCH (74, 60) in Embodiment 2. A generator polynomial of the extended BCH (76, 60) over GF(2⁷) may be expressed as:

$$g 2 ( x ) = g ( x ) ( {x}^{2} + 1 ) = ( {x}^{7} + {x}^{3} + 1 ) ( {x}^{7} + {x}^{3} + {x}^{2} + x + 1 ) ( {x}^{2} + 1 ) = {x}^{16} + {x}^{14} + {x}^{11} + {x}^{10} + {x}^{9} + {x}^{7} + {x}^{5} + {x}^{3} + x + 1$$

60 bits to be encoded are respectively used as coefficients of a polynomial with a highest degree of 59, to obtain an information polynomial m(x). A remainder polynomial r(x) is obtained, using modulo-2 division, by dividing x¹⁶m(x) by g2(x), and coefficients of items in r(x) are a parity sequence P[0:15]. Finally, the information sequence A and the parity sequence P form a complete codeword of inner encoding (135, 119), which is denoted as C[0:134]=[c₀, c₁, . . . , c₁₃₄] and may be represented as

$$\{ \begin{matrix}{c}_{i} = {a}_{i} , & i ∈ [ 0 , 118 ] \\ {c}_{i} = {p}_{i - 119} , & i ∈ [ 119 , 134 ]\end{matrix} .$$

### Embodiment 5: In a DP-16QAM Modulation Scheme, Inner Encoding is (135, 119) with (76, 60) Over GF(2⁸) Encoding

As shown in FIG. 9, a length of an inner encoded codeword is 135 bits, where a length of an information sequence is 119 bits, and a length of a parity sequence is 16 bits. First, a to-be-encoded sequence B[0:59] is generated based on an information sequence A[0:118] in a manner the same as that in Embodiment 1. Then, BCH (76, 60) encoding is performed on the to-be-encoded sequence to generate a 16-bit parity bit [p₀, p₁, . . . , p₁₅]. BCH (76, 60) is obtained by shortening, by 179 bits, BCH (255, 239) constructed over a finite field GF(2⁸) with t=2. A generator polynomial of the BCH (76, 60) over GF(2⁸) may be expressed as:

$$g 3 ( x ) = M 1 ( x ) M 3 ( x ) = ( {x}^{8} + {x}^{4} + {x}^{3} + {x}^{2} + 1 ) ( {x}^{8} + {x}^{6} + {x}^{5} + {x}^{4} + {x}^{2} + x + 1 ) = {x}^{16} + {x}^{14} + {x}^{13} + {x}^{11} + {x}^{10} + {x}^{9} + {x}^{8} + {x}^{6} + {x}^{5} + x + 1$$

60 bits to be encoded are respectively used as coefficients of a polynomial with a highest degree of 59, to obtain an information polynomial m(x). A remainder polynomial r(x) is obtained, using modulo-2 division, by dividing x¹⁶m(x) by g3(x), and coefficients of items in r(x) are a parity sequence P[0:15]. Finally, the information sequence A and the parity sequence P form a complete codeword of inner encoding (135, 119), which is denoted as C[0:134]=[c₀, c₁, . . . , c₁₃₄] and may be represented as

$$\{ \begin{matrix}{c}_{i} = {a}_{i} , & i ∈ [ 0 , 118 ] \\ {c}_{i} = {p}_{i - 119} , & i ∈ [ 119 , 134 ]\end{matrix} .$$

### Embodiment 6: In a DP-16QAM Modulation Scheme, Inner Encoding is (136, 119) with (77, 60) Over GF(2⁸) Encoding

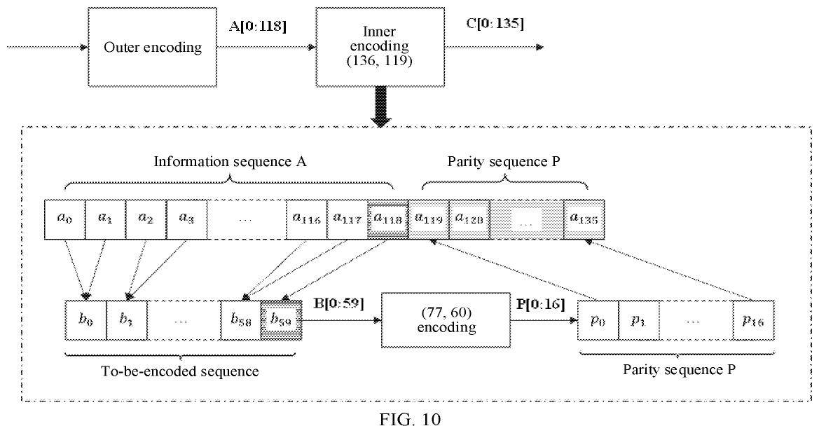

FIG. 10 is a diagram of a fifth application scenario of inner encoding according to an embodiment of this disclosure. As shown in FIG. 10, a length of an inner encoded codeword is 136 bits, where a length of an information sequence is 119 bits, and a length of a parity sequence is 17 bits. First, a to-be-encoded sequence B[0:59] is generated based on an information sequence A[0:118] in a manner the same as that in Embodiment 1. Then, extended BCH (77, 60) encoding is performed on the to-be-encoded sequence to generate a 17-bit parity bit [p₀, p₁, . . . , p₁₆]. Extended BCH (77, 60) is obtained by adding single-bit parity check based on the BCH (76, 60) in Embodiment 5. A generator polynomial of the extended BCH (77, 60) over GF(2⁸) may be expressed as:

$$g 4 ( x ) = g 3 ( x ) ( x + 1 ) = ( {x}^{8} + {x}^{4} + {x}^{3} + {x}^{2} + 1 ) ( {x}^{8} + {x}^{6} + {x}^{5} + {x}^{4} + {x}^{2} + x + 1 ) ( x + 1 ) = {x}^{17} + {x}^{16} + {x}^{15} + {x}^{13} + {x}^{12} + {x}^{8} + {x}^{7} + {x}^{5} + {x}^{2} + 1$$

60 bits to be encoded are respectively used as coefficients of a polynomial with a highest degree of 59, to obtain an information polynomial m(x). A remainder polynomial r(x) is obtained, using modulo-2 division, by dividing x¹⁷m(x) by g4(x), and coefficients of items in r(x) are a parity sequence P[0:16]. Finally, the information sequence A and the parity sequence P form a complete codeword of inner encoding (136, 119), which is denoted as C[0:135]=[c₀, c₁, . . . , c₁₃₅] and may be represented as

$$\{ \begin{matrix}{c}_{i} = {a}_{i} , & i ∈ [ 0 , 118 ] \\ {c}_{i} = {p}_{i - 119} , & i ∈ [ 119 , 135 ]\end{matrix} .$$

### Embodiment 7: In a DP-16QAM Modulation Scheme, Inner Encoding is (137, 119) with (78, 60) Over GF(2⁸) Encoding

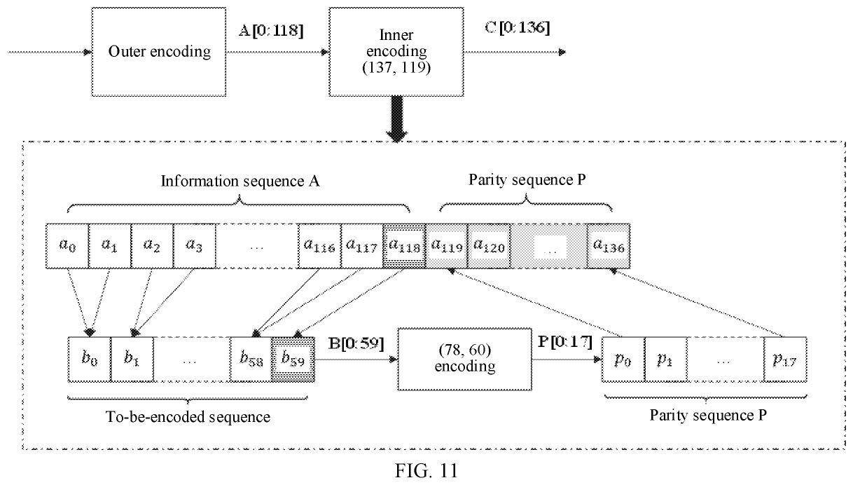

FIG. 11 is a diagram of a sixth application scenario of inner encoding according to an embodiment of this disclosure. As shown in FIG. 11, a length of an inner encoded codeword is 137 bits, where a length of an information sequence is 119 bits, and a length of a parity sequence is 18 bits. First, a to-be-encoded sequence B[0:59] is generated based on an information sequence A[0:118] in a manner the same as that in Embodiment 1. Then, extended BCH (78, 60) encoding is performed on the to-be-encoded sequence to generate an 18-bit parity bit [p₀, p₁, . . . , p₁₇]. Extended BCH (78, 60) is obtained by adding double-bit parity check based on the BCH (76, 60) in Embodiment 5. A generator polynomial of the extended BCH (78, 60) over GF(2⁸) may be expressed as:

$$g 5 ( x ) = g 3 ( x ) ( {x}^{2} + 1 ) = ( {x}^{8} + {x}^{4} + {x}^{3} + {x}^{2} + 1 ) ( {x}^{8} + {x}^{6} + {x}^{5} + {x}^{4} + {x}^{2} + x + 1 ) ( {x}^{2} + 1 ) = {x}^{18} + {x}^{15} + {x}^{14} + {x}^{12} + {x}^{9} + {x}^{7} + {x}^{6} + {x}^{5} + {x}^{3} + {x}^{2} + x + 1$$

60 bits to be encoded are respectively used as coefficients of a polynomial with a highest degree of 59, to obtain an information polynomial m(x). A remainder polynomial r(x) is obtained, using modulo-2 division, by dividing x¹⁸m(x) by g5(x), and coefficients of items in r(x) are a parity sequence P[0:17]. Finally, the information sequence A and the parity sequence P form a complete codeword of inner encoding (137, 119), which is denoted as C[0:136]=[c₀, c₁, . . . , c₁₃₆] and may be represented as

$$\{ \begin{matrix}{c}_{i} = {a}_{i} , & i ∈ [ 0 , 118 ] \\ {c}_{i} = {p}_{i - 119} , & i ∈ [ 119 , 136 ]\end{matrix} .$$

### Embodiment 8: In a DP-64QAM Modulation Scheme, Inner Encoding is (128, 119) with(50, 41) Over GF(2⁷) Encoding

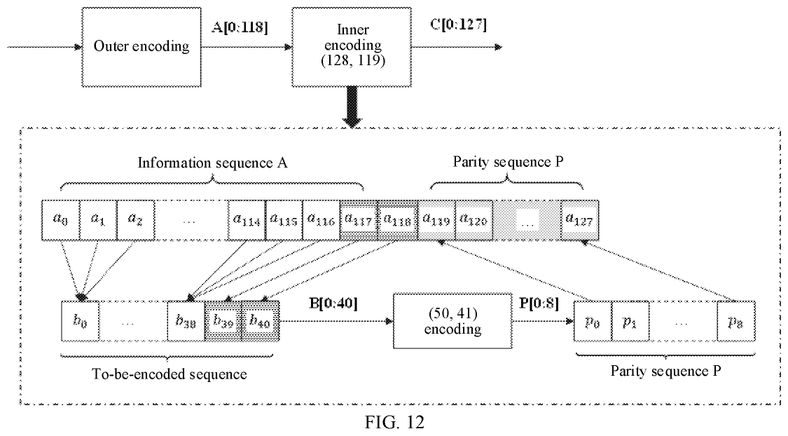

FIG. 12 is a diagram of a seventh application scenario of inner encoding according to an embodiment of this disclosure. As shown in FIG. 12, a length of an inner encoded codeword is 128 bits, where a length of an information sequence is 119 bits, and a length of a parity sequence is 9 bits. First, 117 bits are selected from the 119-bit information sequence A to form a sequence A′, and are denoted as

$${A}^{′} = [ {a}_{0}^{′} , {a}_{1}^{′} , ⋯ , {a}_{116}^{′} ] .$$

A′ may be any 117 bits in A. To facilitate subsequent channel interleaving and modulation, first 117 bits in A may be selected as A′, that is, A′=[a₀, a₁, . . . , a₁₁₆]. Then, consecutive three bits in A′ are grouped into one group to perform an exclusive OR operation, so as to obtain 39 bits [b₀, b₁, . . . , b₃₈]. In addition, bits in A that are not selected into A′ are denoted as A\A′, a grouping and exclusive OR operation is skipped for A\A′, and A\A′ is combined with b₀~b₃₈ to form a to-be-encoded sequence B[0:40]=[b₀, b₁, . . . , b₄₀], which is expressed as follows:

$$\{ \begin{matrix}{b}_{i} = {a}_{3 i}^{′} ⋀ {a}_{3 i + 1}^{′} ⋀ {a}_{3 i + 2}^{′} , & i ∈ [ 0 , 38 ] \\ {b}_{i} = A ∖ {A}^{′} , & i ∈ [ 39 , 40 ]\end{matrix} .$$

Then, extended Hamming code (50, 41) encoding is performed on the to-be-encoded sequence to generate a 9-bit parity bit [p₀, p₁, . . . , p₈]. Extended Hamming code (50, 41) is obtained by shortening, by 79 bits, a double-bit extended Hamming code constructed over a finite field GF(2⁷). Finally, a codeword C[0:127]=[c₀, c₁, . . . , c₁₂₇] generated by inner encoding (128, 119) may be represented as

$$\{ \begin{matrix}{c}_{i} = {a}_{i} , & i ∈ [ 0 , 118 ] \\ {c}_{i} = {p}_{i - 119} , & i ∈ [ 119 , 127 ]\end{matrix} .$$

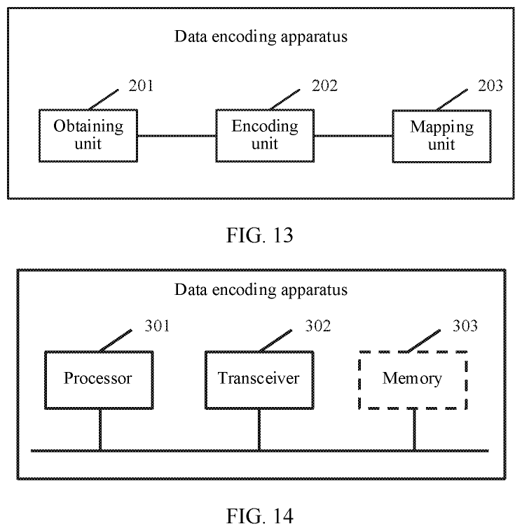

FIG. 13 is a diagram of a structure of a data encoding apparatus according to an embodiment of this disclosure. As shown in FIG. 13, the data encoding apparatus includes an obtaining unit 201, an encoding unit 202, and a mapping unit 203. The obtaining unit 201 is configured to perform an operation in step 101, the encoding unit 202 is configured to perform operations in step 102 and step 103, and the mapping unit 203 is configured to perform an operation in step 104. It should be understood that the data encoding apparatus provided in this disclosure may alternatively be implemented in another manner. For example, division into the units in the foregoing apparatus is merely logical function division and may be other division in actual implementation. For example, a plurality of units or components may be combined or integrated into another system. In addition, functional units in embodiments of this disclosure may be integrated into one processing unit, may be independent physical units, or two or more functional units may be integrated into one processing unit. The integrated unit may be implemented in a form of hardware, or may be implemented in a form of a software functional unit.

FIG. 14 is a diagram of another structure of a data encoding apparatus according to an embodiment of this disclosure. As shown in FIG. 14, the data encoding apparatus includes a processor 301 and a transceiver 302. The processor 301 and the transceiver 302 are interconnected through a line. The transceiver 302 is configured to perform data receiving and sending operations, and the processor 301 is configured to perform other operations than data receiving and sending operations. In a possible implementation, the processor 301 may include the encoding unit 202 and the mapping unit 203 shown in FIG. 13, and the transceiver 302 includes the obtaining unit 201 shown in FIG. 13. Optionally, the data encoding apparatus may further include a memory 303. The memory 303 is configured to store program instructions and data.

An embodiment of this disclosure further provides a chip. The chip integrates a circuit and one or more interfaces that are configured to implement a function of the processor 301. When a memory is integrated into the chip, the chip may complete the method steps in any one or more of the foregoing embodiments. When no memory is integrated into the chip, the chip may be connected to an external memory through an interface. The chip implements, based on program code stored in the external memory, actions performed by the transmitter device or the receiver device in the foregoing embodiments.

Finally, it should be noted that, the foregoing descriptions are merely specific implementations of this disclosure, but are not intended to limit the protection scope of this disclosure. Any variation or replacement readily figured out by a person skilled in the art within the technical scope disclosed in this disclosure shall fall within the protection scope of this disclosure. Therefore, the protection scope of this disclosure shall be subject to the protection scope of the claims.

1. A method, comprising:
obtaining consecutive k bits in a first data stream based on first forward error correction (FEC) encoding, wherein k is an odd number greater than 1, wherein the consecutive k bits comprise a bit set and a target bit, wherein the bit set comprises (k−1)/2 bit subsets, and wherein each of the (k−1)/2 bit subsets comprises two bits; and
performing inner encoding on the consecutive k bits to obtain a codeword, wherein the inner encoding comprises:
performing an exclusive OR operation on the two bits in each of the k−1)/2 bit subsets to obtain a total of (k−1)/2 bits; and
performing second FEC encoding on a bit sequence that comprises the (k−1)/2 bits and the target bit to obtain p parity bits,
wherein the codeword comprises the consecutive k bits and the p parity bits, and
wherein p is an integer greater than or equal to 1.

2. The method of claim 1, wherein the two bits in each of the (k−1)/2 bit subsets are two adjacent bits in the consecutive k bits.

3. The method of claim 1, wherein either the p parity bits are located after the consecutive k bits in the codeword and the target bit is a last bit in the consecutive k bits, or the p parity bits are located before the consecutive k bits in the codeword and the target bit is a first bit in the consecutive k bits.

4. The method of claim 1, wherein after performing the inner encoding, the method further comprises performing symbol mapping and polarization distribution on eight bits in a second data stream to obtain one dual-polarization 16-quadrature amplitude modulation (DP-16QAM) symbol, wherein the second data stream comprises at least one codeword that is based on the inner encoding, wherein the eight bits comprise two bits from each of four bit subsets selected from the (k−1)/2 bit subsets, wherein the four bit subsets are respectively mapped to an I component in an X polarization direction, a Q component in the X polarization direction, an I component in a Y polarization direction, and a Q component in the Y polarization direction of the DP-16QAM symbol, and wherein the X polarization direction and the Y polarization direction are orthogonal to each other.

5. The method of claim 1, wherein the second FEC encoding is Bose-Chaudhuri-Hocquenghem (BCH) encoding or extended BCH encoding, wherein the BCH encoding or the extended BCH encoding is performed over a finite field GF(2\hat{ }m) with t-bit error correction, wherein both m and t are integers greater than or equal to 1, wherein mt≤p, and wherein
$$\frac{k + 1}{2} + p \leq {2}^{m} - 1 .$$

6. The method of claim 5, wherein k=119, and wherein the GF(2\hat{ }m) is GF(2\hat{ }8) or GF(2\hat{ }7).

7. The method of claim 5, wherein a length of the codeword is n, wherein the second FEC encoding is the BCH encoding, and wherein a correspondence among n, k, GF(2\hat{ }m), t, and p is one of the following:
$$n = 13 \; 3 , k = 119 , GF ( 2 ⋀ m ) = GF ( 2 ⋀ 7 ) , t = 2 , and p = 14 ; \underline{or} [ [ and ] ]$$
$$n = 135 , k = 119 , GF ( 2 ⋀ m ) = GF ( 2 ⋀ 8 ) , t = 2 , and p = 16 .$$

8. The method of claim 5, wherein a length of the codeword is n, wherein the second FEC encoding is the extended BCH encoding, wherein the p parity bits comprise a cyclic redundancy check (CRC) extended check field of q bits, and wherein a correspondence among n, k, GF(2\hat{ }m), t, p, and q is one of the following:
$$n = 12 \; 8 , k = 119 , GF ( 2 ⋀ m ) = GF ( 2 ⋀ 7 ) , t - 1 , p = 9 , and q = 2 ;$$
$$n = 134 , k = 119 , GF ( 2 ⋀ m ) = GF ( 2 ⋀ 7 ) , t = 2 , p = 15 , and q = 1 ;$$
$$n = 135 , k = 119 , GF ( 2 ⋀ m ) = GF ( 2 ⋀ 7 ) , t = 2 , p = 16 , and q = 2 ;$$
$$n = 136 , k = 119 , GF ( 2 ⋀ m ) = GF ( 2 ⋀ 8 ) , t = 2 , p = 17 , and q = 1 ; \underline{or} [ [ and ] ]$$
$$n = 137 , k = 119 , GF ( 2 ⋀ m ) = GF ( 2 ⋀ 8 ) , t = 2 , p = 18 , and q = 2 .$$

9. A data encoding apparatus, comprising:
a memory configured to store instructions; and
a processor coupled to the memory and configured to execute the instructions to cause the data encoding apparatus to:
obtain consecutive k bits in a first data stream based on first forward error correction (FEC) encoding, wherein k is an odd number greater than 1, wherein the consecutive k bits comprise a bit set and a target bit, wherein the bit set comprises (k−1)/2 bit subsets, and wherein each of the (k−1)/2 bit subsets comprises two bits; and
perform inner encoding on the consecutive k bits to obtain a codeword, wherein the inner encoding comprises:
performing an exclusive OR operation on the two bits in each of the (k−1)/2 bit subsets to obtain a total of (k−1)/2 bits; and
performing second FEC encoding on a bit sequence that comprises the (k−1)/2 bits and the target bit to obtain p parity bits,
wherein the codeword comprises the consecutive k bits and the p parity bits, and
wherein p is an integer greater than or equal to 1.

10. The data encoding apparatus of claim 9, wherein the two bits in each of the (k−1)/2 bit subsets are two adjacent bits in the consecutive k bits.

11. The data encoding apparatus of claim 9, wherein either the p parity bits are located after the consecutive k bits in the codeword and the target bit is a last bit in the consecutive k bits, or the p parity bits are located before the consecutive k bits in the codeword and the target bit is a first bit in the consecutive k bits.

12. The data encoding apparatus of claim 9, wherein after performing the inner encoding, the processor is further configured to execute the instructions to cause the data encoding apparatus to perform symbol mapping and polarization distribution on eight bits in a second data stream to obtain one dual-polarization 16-quadrature amplitude modulation (DP-16QAM) symbol, wherein the second data stream comprises at least one codeword based on the inner encoding, wherein the eight bits comprise two bits from each of four bit subsets selected from the (k−1)/2 bit subsets, wherein the four bit subsets are respectively mapped to an I component in an X polarization direction, a Q component in the X polarization direction, an I component in a Y polarization direction, and a Q component in the Y polarization direction of the DP-16QAM symbol, and wherein the X polarization direction and the Y polarization direction are orthogonal to each other.

13. The data encoding apparatus of claim 9, wherein the second FEC encoding is Bose-Chaudhuri-Hocquenghem (BCH) encoding or extended BCH encoding, wherein the BCH encoding or the extended BCH encoding is performed over a finite field GF(2\hat{ }m) with t-bit error correction, wherein both m and t are integers greater than or equal to 1, wherein mt≤p, and wherein
$$\frac{k + 1}{2} + p \leq {2}^{m} - 1 .$$

14. The data encoding apparatus of claim 13, wherein k=119, and wherein the GF(2\hat{ }m) is GF(2\hat{ }8) or GF(2\hat{ }7).

15. The data encoding apparatus of claim 13, wherein a length of the codeword is n, wherein the second FEC encoding is the BCH encoding, and wherein a correspondence among n, k, GF(2\hat{ }m), t, and p is one of the following:
$$n = 133 , k = 119 , GF ( 2 ⋀ m ) = GF ( 2 ⋀ 7 ) , t = 2 , and p = 14 ; \underline{or} [ [ and ] ]$$
$$n = 13 \; 5 , k = 119 , GF ( 2 ⋀ m ) = GF ( 2 ⋀ 8 ) , t = 2 , and p = 16 .$$

16. The data encoding apparatus of claim 13, wherein a length of the codeword is n, wherein the second FEC encoding is the extended BCH encoding, wherein the p parity bits comprise a cyclic redundancy check (CRC) extended check field of q bits, and wherein a correspondence among n, k, GF(2\hat{ }m), t, p, and q is one of the following:
$$n = 128 , k = 119 , GF ( 2 ⋀ m ) = GF ( 2 ⋀ 7 ) , t - 1 , p = 9 , and q = 2 ;$$
$$n = 13 \; 4 , k = 119 , GF ( 2 ⋀ m ) = GF ( 2 ⋀ 7 ) , t = 2 , p = 15 , and q = 1 ;$$
$$n = 13 \; 5 , k = 119 , GF ( 2 ⋀ m ) = GF ( 2 ⋀ 7 ) , t = 2 , p = 16 , and q = 2 ;$$
$$n = 13 \; 6 , k = 119 , GF ( 2 ⋀ m ) = GF ( 2 ⋀ 8 ) , t = 2 , p = 17 , and q = 1 ; \underline{or} [ [ and ] ]$$
$$n = 13 \; 7 , k = 119 , GF ( 2 ⋀ m ) = GF ( 2 ⋀ 8 ) , t = 2 , p = 18 , and q = 2 .$$

17. A data encoding apparatus, comprising:
a memory configured to store instructions; and
a processor coupled to the memory and configured to execute the instructions to cause the data encoding apparatus to:
obtain consecutive k bits in a first data stream based on first forward error correction (FEC) encoding, wherein k is an integer greater than or equal to 3, wherein the consecutive k bits comprise v bit subsets, wherein each of the v bit subsets comprises three bits, and wherein v is an integer greater than or equal to 1; and
perform inner encoding on the consecutive k bits to obtain a codeword, wherein the inner encoding comprises:
performing an exclusive OR operation on the three bits in each of the v bit subsets to obtain a total of v bits; and
performing second FEC encoding on a bit sequence that comprises the v bits to obtain p parity bits,
wherein the codeword comprises the consecutive k bits and the p parity bits, and
wherein p is an integer greater than or equal to 1.

18. The data encoding apparatus of claim 17, wherein the three bits in each of the v bit subsets are three consecutive bits in the consecutive k bits.

19. The data encoding apparatus of claim 17, wherein k=v×3.

20. The data encoding apparatus of claim 17, wherein the consecutive k bits further comprise r target bits, wherein k=v×3+r, r=1 or 2, and wherein performing the second FEC encoding comprises performing the second FEC encoding on the bit sequence that comprises the v bits and the r target bits to obtain the p parity bits.
